(19) United States
(12) Patent Application Publication
(10) Pub. No.: US 2024/0192918 A1
(43) Pub. Date: Jun. 13, 2024

(54) SORTING

(71) Applicant: Imagination Technologies Limited, Kings Langley (GB)

(72) Inventor: Fabrizio Cabaleiro, Hertfordshire (GB)

(21) Appl. No.: 18/534,595

(22) Filed: Dec. 9, 2023

(30) Foreign Application Priority Data
Dec. 9, 2022 (GB) 2218576.3
Dec. 9, 2022 (GB) 2218580.5

(51) Int. Cl. G06F 7/02; G06F 7/24; G06F 7/32; H03K 19/21

(52) U.S. Cl. CPC G06F 7/02; G06F 7/24; G06F 7/32; H03K 19/21

(57) ABSTRACT

A method of comparing a plurality of elements in a first array, using a neural network accelerator having fixed-function hardware, the method including the steps of generating a second array, the second array having the position of each pair of elements to be compared swapped, comparing respective elements of the first array and the second array to generate a third array to identify which of the respective elements of the first and second array is larger or smaller and generating a result array, using at least the third array, by using a fourth predetermined array, the fourth predetermined array indicating the position in the result array of the larger and the smaller of each element of each pair of elements.

### CROSS-REFERENCE TO RELATED APPLICATIONS AND CLAIM OF PRIORITY

This application claims foreign priority under 35 U.S.C. 119 from United Kingdom patent applications 2218576.3 and 2218580.5, both filed on 9 Dec. 2022, both of which are incorporated by reference herein in their entirety.

### TECHNICAL FIELD

The present invention relates to a method of sorting data elements. In particular it relates to sorting data elements within a neural network accelerator (NNA)

### BACKGROUND

Neural Network accelerators (NNAs) are optimised to handle neural network workloads by using large scale array and elementwise operations on the large scale arrays. Functions which can be performed using (only) elementwise operations are therefore particularly useful.

Some neural network functions, for example non-maximum suppression (NMS, which can be used to process object predictions in object detection networks) and Argsort (which returns an array of indices of sorted data), require a sorting step. NMS removes predicted areas which are very similar and would be considered “duplicated”, it removes all overlapping areas but the one with the greatest probability. In Argsort the indices of data in an array are returned in an order corresponding to a sorted order of the data, and must therefore be compared and swapped as necessary. Many NNAs currently have no facility to sort inputs and thus the sorting function is currently performed by a CPU, either externally or integrated within the NNA.

A CPU will generally use an algorithm such as quicksort. The time taken is non-deterministic so the time taken to sort the data will depend on the order in which the data is in. As there is no definitive time the time allowed for this function by the NNA must be set to the worst case scenario, such as the numbers being entirely reversed. This may be longer than the function actually takes in a non-worst case scenario.

Both the non-deterministic time taken for sorting and the use of a CPU either externally or integrated within the NNA are not ideal.

To expedite sorting over the current quicksort method it would be desirable to provide a method of sorting using the NNA itself.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

According to the invention there is method comprising comparing pairs of elements in a first array. The method comprises generating a second array with elements of the pairs to compared swapped. The first and second arrays are compared to generate a third array which identifies which of the respective elements of the first and second array is larger or smaller. A fourth, predetermined array is used, together with at least the third array to generate a result array. The fourth predetermined array indicates the position in the result array of the larger and smaller of each element of each pair of elements. The comparisons of all pairs of the elements are performed in parallel and, advantageously, all of these functions can be performed using elementwise operations. Thus, the entire method can be carried out using a neural network accelerator and no dedicated sorting hardware is required. Furthermore, the time taken to perform the operation is deterministic.

Generating a result array may comprise processing, using a XOR function, the third array with the fourth predetermined array to output a fifth array which indicates whether each pair of elements should be taken from the first array in which the pair of elements are in the original position or the second array in which the pair of elements are in the swapped position. Based on the information in the fifth array a result array is generated using elements from at least one of the first array and the second array.

The fifth array may be compared to a predetermined value and comparing the fifth array to a predetermined value may comprise one or more of the following functions: more than, less than, more than or equal to, less than or equal to.

Alternatively, the third array may comprise the smaller of each pair of elements and generating a result array may comprise comparing respective elements of the first array and the second array to generate a fifth array comprising the larger of each pair. There is thus an array comprising the minimum of each pair and another array comprising the maximum of each pair. The method then compares elements of a fourth predetermined array to a predetermined value to determine whether an element should be taken from the third array or the fifth array to generate the result array.

Comparing elements of a fourth predetermined array to a predetermined value may comprise one or more of the following functions: more than, less than, more than or equal to, less than or equal to.

The method may be repeated a plurality of times, each time forming comparison step in a bitonic sorting algorithm, the method being repeated until the bitonic sorting algorithm is complete. For each repetition, the pairs of elements to be compared are independent and selected according to the comparison step in the bitonic sorting algorithm. The fourth predetermined array may be independent for each repetition of the method and is predetermined according to the comparison step in the bitonic sorting algorithm. Such a method sorts the elements in the array into an incremental order.

If the number of elements in the first array is not a power of 2 elements may be added to the first array until the number of elements is a power of 2 and wherein each element added is same and is either a maximum value or a minimum value.

Elements of the array may be compound numbers with the most significant bits comprising the element and the least significant bits comprising metadata. An example of metadata may be an address reference.

The elements to be sorted may be object predictions in a non-maximum suppression layer in an object detection network.

If the number of elements in an array is not a power of 2 an array may be divided into a plurality of sub-arrays and, at a later stage, the sub-arrays are then merged back into an output array. The merging steps comprise generating an intermediate array comprising the first element from each sub-array, outputting the maximum or minimum element as the next element in an output array, replacing the maximum or minimum element in the intermediate array with a new element, wherein the new element is the next element in the respective sub-array; and determining a size order of the elements of the intermediate array, wherein the steps of outputting the maximum or minimum element, replacing the maximum or minimum element and determining the size order of the elements of the intermediate array are repeated until all the elements from the plurality of sub-arrays have been output to the output array. As an example, the method described above could be performed on each of the sub-arrays prior to merging.

Outputting the maximum or minimum element as the next element in an output array and replacing the maximum or minimum element in the respective sub-array may comprise accessing a different set of program instructions based on the determined size order of the elements in the intermediate array.

The sub-arrays may initially be ordered based on the first element of each of the plurality of sub-arrays.

If a sub-array is not of size 2ⁿ one or more additional elements may be added at the end of each of the respective sub-arrays until the sub-array is of size 2ⁿ. The additional elements are the maximum data value if the elements of the plurality of sub-arrays are arranged in ascending order or the minimum data value if the elements of the plurality of sub-arrays are arranged in descending order. Thus, each sub-array may be made to be of size 2ⁿ.

Prior to generating the intermediate array a maximum or minimum value may be added as a supplementary element to each sub-array. The supplementary elements will eventually fill the intermediate array but will not be output as they will not be the smallest (or largest) elements. If a sub-array has been increased to size 2ⁿ for sorting, a further supplementary element is added so the total sub-array is of length 2ⁿ+1.

The method may further comprise determining whether all the elements (but not supplementary elements, which are place holders) of each of the sub-arrays has been output to the output array. If all the elements of the sub-arrays have been output to the output array then the merge steps no longer need to be repeated. Determining whether all the elements of the each of the sub-arrays have been output to the output array may comprise counting the number of elements output to the output array and determining whether it is equal to the number of elements (excluding supplementary elements) in all of the sub-arrays.

The steps described above for merging sub-arrays may be carried out using elementwise operations.

The elements to be sorted may be object predictions in a non-maximum suppression layer in an object detection network.

The method of merging sub-arrays is particularly useful, and may be used when a neural network accelerator does not comprise dedicated sorting hardware.

There may be provided a non-transitory computer readable storage medium having stored thereon computer readable code configured to cause the method of merging to be performed when the code is run.

A non-transitory computer readable storage medium having stored thereon a computer readable description of a graphics processing system as described above that, when processed in an integrated circuit manufacturing system, causes the integrated circuit manufacturing system to manufacture an integrated circuit embodying the graphics processing system configured to either merge sub-arrays or compare pairs.

An image processing method comprising a method as described above. The invention may comprise a graphics processing system configured to perform the method described above. The graphics processing system may be embodied in hardware on an integrated circuit.

The above features may be combined as appropriate, as would be apparent to a skilled person, and may be combined with any of the aspects of the examples described herein.

### BRIEF DESCRIPTION OF THE DRAWINGS

Examples will now be described in detail with reference to the accompanying drawings in which:

FIG. 1 shows a bitonic sorting algorithm;

FIG. 2 depicts an alternative bitonic sorting algorithm;

FIG. 3 depicts a bitonic sorting algorithm for 4 elements;

FIG. 4 depicts arrays used in a first phase of a bitonic sorting algorithm;

FIG. 5 depicts arrays used in a second phase of a bitonic sorting algorithm;

FIG. 6 depicts arrays used in a third phase of a bitonic sorting algorithm;

FIG. 7 depicts a method according to the invention;

FIG. 8 depicts arrays used in a first phase of a bitonic sorting algorithm;

FIG. 9 depicts arrays used in a second phase of a bitonic sorting algorithm;

FIG. 10 depicts arrays used in a third phase of a bitonic sorting algorithm;

FIG. 11 depicts a method according to the invention;

FIG. 12 depicts a method according to the invention;

FIG. 13 is a graph depicting the clock cycles used in sorting arrays of different sizes using the present invention and a quick sort method;

FIG. 14a, FIG. 14b, FIG. 15a, FIG. 15b, FIG. 16a, FIG. 16b, FIG. 17a and FIG. 17b depict arrays and an intermediate array used in a method of merging a plurality of sorted sub-arrays;

FIG. 18 depicts a method according to the invention;

FIG. 19 shows a computer system in which a graphics processing system is implemented; and

FIG. 20 shows an integrated circuit manufacturing system for generating an integrated circuit embodying a graphics processing system.

The accompanying drawings illustrate various examples. The skilled person will appreciate that the illustrated element boundaries (e.g., boxes, groups of boxes, or other shapes) in the drawings represent one example of the boundaries. It may be that in some examples, one element may be designed as multiple elements or that multiple elements may be designed as one element. Common reference numerals are used throughout the figures, where appropriate, to indicate similar features.

### DETAILED DESCRIPTION

The following description is presented by way of example to enable a person skilled in the art to make and use the invention. The present invention is not limited to the embodiments described herein and various modifications to the disclosed embodiments will be apparent to those skilled in the art.

Embodiments will now be described by way of example only.

A bitonic sorting algorithm provides a way of sorting elements in a predetermined number of steps. As a predetermined number of steps is used the time taken for a bitonic sorting algorithm is deterministic. It has been recognised that a deterministic sorting time would be preferable to simplify scheduling within an NNA.

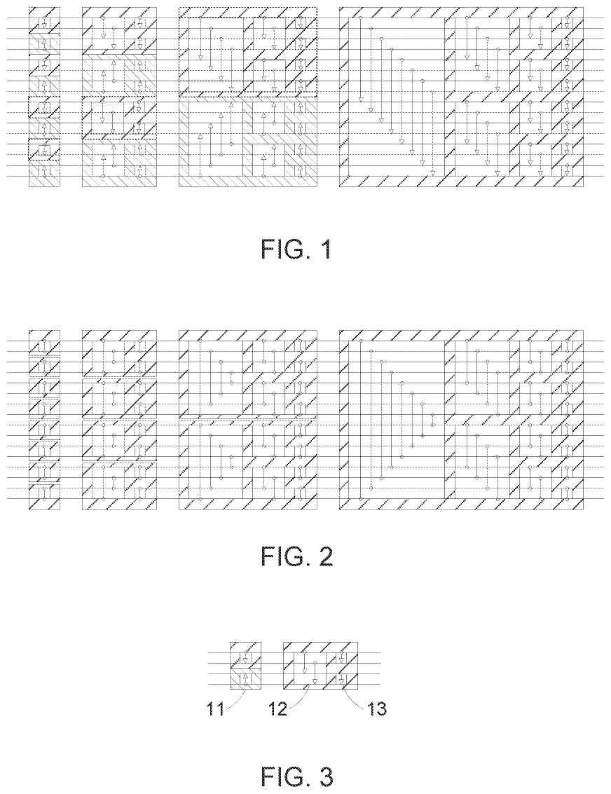

FIG. 1 depicts a bitonic sorting algorithm for 16 inputs (represented by the lines going from left to right). In a first stage (the first set of cross-hatched boxes on the left of FIG. 1) adjacent pairs of elements are compared, with the smaller of the numbers being moved to the position at the end of the arrow. The second stage comprises sorting groups of four using two sorting phases (i.e. each phase comprises each position being compared to one other, and this happens twice for each position in the second stage). Again, for each pair compared, the smaller element is located, or moved, to the end of the arrow. A third stage sorts groups of eight and comprises three phases. Lastly, a fourth stage comprises four sorting phases and sorts the group of 16. Thus, 16 elements can be sorted in 10 steps in which every element is compared to another. So an array of 2ⁿ can be sorted in n(n+1)/2 phases.

An alternative bitonic sorting algorithm is depicted in FIG. 2. In this bitonic sorting algorithm each pair of data elements is always sorted in the same direction. So, the larger of each pair of elements can be moved to the bottom, resulting in an ascending sequence. Alternatively, the larger of each pair of elements can be moved to the top, resulting in a descending sequence.

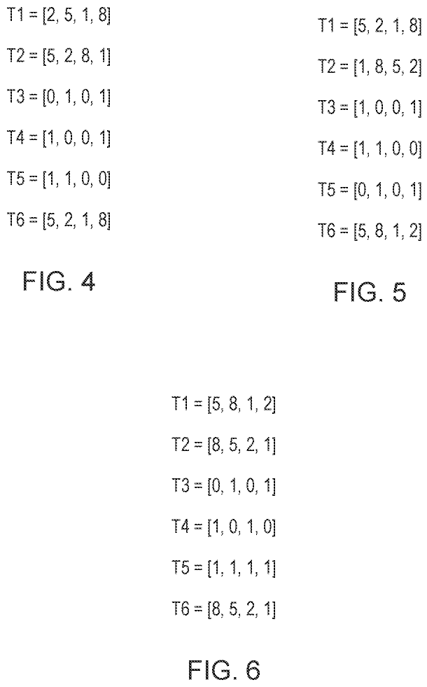

FIG. 3 depicts a bitonic sorting arrangement for 4 elements. As can be seen, it has 3 phases, 11, 12, 13. The steps to achieve the first phase will now be described. The first sorting step in the phase compares adjacent pairs of elements. An example array T1 of four elements to be sorted is depicted in FIG. 4. The array is [2, 5, 1, 8].

In the first phase the first and second elements and the third and fourth elements are compared. The first step in this phase is to generate a second array T2 in which the first and second elements are swapped and the third and fourth elements are swapped. This can be achieved using a memory manipulation function within the neural network and an example of this is given in EP21177174. The array T2 of [5, 2, 8, 1] is depicted in FIG. 4.

The next step is to compare respective elements of T1 and T2 using a less than function to generate a third array T3. If T1 is less than T2 then a 0 is output and if T1 is not less than T2 a 1 is output. This can be expressed as T3=LessThan(T1, T2, 0, 1). For the example of FIG. 4 T3=[0, 1, 0, 1], as depicted in FIG. 4. If the original pairs of elements had an ascending order then [0, 1] will be output whereas if the original pairs of elements had a descending order then [1, 0] will be output at this step.

The third step is to use a X or function with the array T3 and a fourth array, T4, to generate a fifth array, T5, which indicates whether a pair of values should be selected from T1 or T2. For the first phase of the four element example T4 is [1, 0, 0, 1], as depicted in FIG. 4. The array T4 is predetermined for each phase by the bitonic sorting algorithm, so different phases of the bitonic sorting algorithm may each have a different array T4 (although, depending on the particular bitonic sorting algorithm, the array T4 for one phase may have the same form as for another) with zeros indicating the destination of the smaller of the pair of elements. For the third step T5=XOR(T3, T4) so, for the present example, T5 is [1, 1, 0, 0]. T5 indicates that, for the first pair of elements, the order in T2 should be output as a final result whereas, for the second pair of elements, the order in T1 should be output as a final result.

The fourth step in the first phase is to use another LessThan function, together with T5, to select pairs of elements from either T1 or T2. This can be expressed as T6=Less Than (T5, 1, T1, T2). If an elements of T5 is less than 1 then T1 is output, whereas if it is not less than 1 T2 is output. So, for the first pair of elements, 1 (from T5) is not less than 1 so the elements from T2 are output. For the second pair of elements, 0 (from T5) is less than 1 so the elements from T1 are output. Thus, T6=[5, 2, 1, 8]. As can be seen, the smaller of 2 and 5 has been moved to the second position in T6. The smaller of 1 and 8 is at the third position in T6. This is as shown in the first phase of FIG. 3.

The output from the first phase is the input to the next phase so, for the second phase, depicted in FIG. 5, T1 is [5, 2, 1, 8]. As can be seen from the second phase, 12, of FIG. 3 the second phase compares the first and third elements and the second and fourth elements. For T2 the first and third elements and the second and fourth elements are swapped so T2 is [1, 8, 5, 2]. Using T3=LessThan(T1, T2, 0, 1)=[1, 0, 0, 1]. For the third step predetermined array T4 [1, 1, 0, 0] is used: the smaller of each pair are moved to the third and fourth positions (indicated by zeros). T4, combined with a XOR function with T3 generates T5=[0, 1, 0, 1]. For the fourth step of the second phase T6=LessThan (T5, 1, T1, T2)=[5, 8, 1, 2]. As can be seen the smaller of 5 and 1 (the first and third elements of T1) is in the third position and the smaller of 2 and 8 (the second and fourth elements of T1).

For the third and final phase of the four element bitonic sorting algorithm, depicted in FIG. 6, T1=[5, 8, 1, 2]. In the final phase the first and second elements and the third and fourth elements are compared. Thus, T2=[8, 5, 2, 1] and T3=LessThan (T1, T2, 0, 1)=[0, 1, 0, 1]. For this phase T4 is [1, 0, 1, 0] because the smaller elements should be moved to the second and fourth positions. Thus T5=XOR(T3, T4)=[1, 1, 1, 1]. Then, finally, T6=LessThan(T5, 1, T1, T2)=[8, 5, 2, 1]. The array has now been sorted from largest element to smallest element.

As will be appreciated, the pairs of elements to be compared, and therefore swapped, to generate T2 for the respective phase, vary according to phase. Similarly T4 also varies according to the phase. The data for both these can be stored and accessed as necessary. One example is that this data can be stored as a series of arrays within the NNA.

Advantageously, all these steps can be implemented within a NNA so that elements within an array can be compared and sorted within the NNA. As the number of phases and steps is determined solely by the number of elements the time taken is deterministic.

The example above uses the function LessThan but the invention could equally be implemented using a more than function to sort the elements in an ascending, rather than descending order. Similarly, a less than or equal to or a more than or equal to function could be used. Similarly a XOR function has been used but any other function used to select the elements could be used.

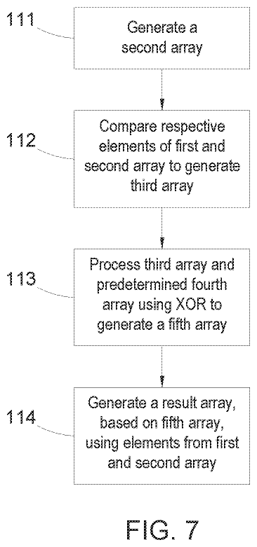

A method of comparing pairs elements in a first array according to the invention is depicted in FIG. 7. In a first step 111 a second array is generated, in which the position of pairs of elements to be compared are swapped. The first and second array are then compared 112 to generate a third array which indicates which of the respective elements of the first and second array is more or less. In a third step 113 a XOR function is used to process the third array and a predetermined fourth array to generate a fifth array. In a fourth step 114 a result array is generated based on information in the fifth array and using elements from at least one of the first array and second array.

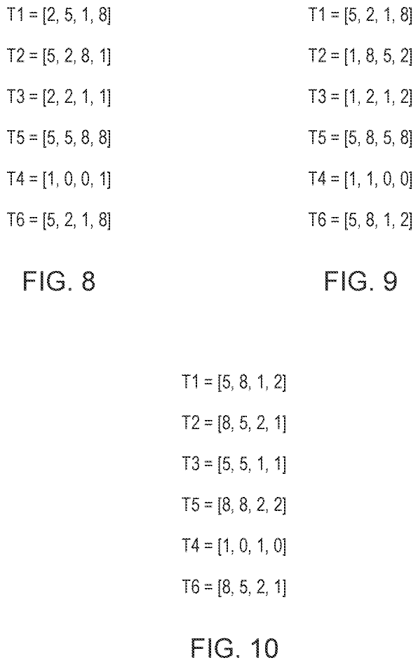

FIGS. 4-7 depict a method of carrying out the invention and FIGS. 8-11 depict an alternative method of carrying out the invention on the same array T1 of four elements. Similar to the earlier method, the first step of each phase comprises generating a second array T2 in which pairs of elements are swapped. In the first phase the first and second elements are swapped and the third and fourth elements are swapped to generate T2 [5, 2, 8, 1]. The arrays of the first phase are depicted in FIG. 8.

The next step is to compare the first and second arrays to generate a third array in which the smaller element of the first and second array is output. Thus, the second step is LessThan(T1, T2, T1, T2) which, for the present example, outputs T3=[2, 2, 1, 1]. The third step is to perform another comparison step but to output the larger element of the first and second array. So the next step is LessThan(T1, T2, T2, T1) and T5=[5, 5, 8, 8]. Thus, the third array includes the smaller element of each pair of elements and the fifth array includes the larger element of each pair of elements. As the skilled person will appreciate, these steps can be performed in either order and different functions including more than, less than and equal to and more than and equal to can be used.

The final step in each phase is to use the fourth array (described above) which indicates the destination of the smaller of each element and compare elements of the fourth predetermined array to a fixed value. If the element is less than 1 then the respective element from array T3 is output (i.e. the smaller element is output). If the element is not less than 1 then the respective element from array T5 is output (i.e. the larger element is output). The final step is LessThan(T4, 1, T3, T5) so T6 is [5, 2, 1, 8].

Just as in the earlier method, the output from one phase is the input to the next phase so the input to the second phase of the method, depicted in FIG. 9, is T1=[5, 2, 1, 8]. In the second phase the first and third elements are compared and the second and fourth elements are compared. For this phase T2=[1, 8, 5, 2], then T3=[1, 2, 1, 2] and T5-[5, 8, 5, 8]. T4 is the same as for the second phase of the method above so T4=[1, 1, 0, 0] and finally T6=[5, 8, 1, 2].

The third and final phase of the method, depicted in FIG. 10, compares the first and second elements and the third and fourth elements and uses the array T4=[1, 0, 1, 0]. T1=[5, 8, 1, 2] so T2=[8, 5, 2, 1]. T3=[5, 5, 1, 1] and T5=[8, 8, 2, 2]. Therefore the final array is T6=[8, 5, 2, 1].

Just as in the first method alternative comparing functions may be used such as LessThan, MoreThan, Less Than or equal or MoreThan or equal.

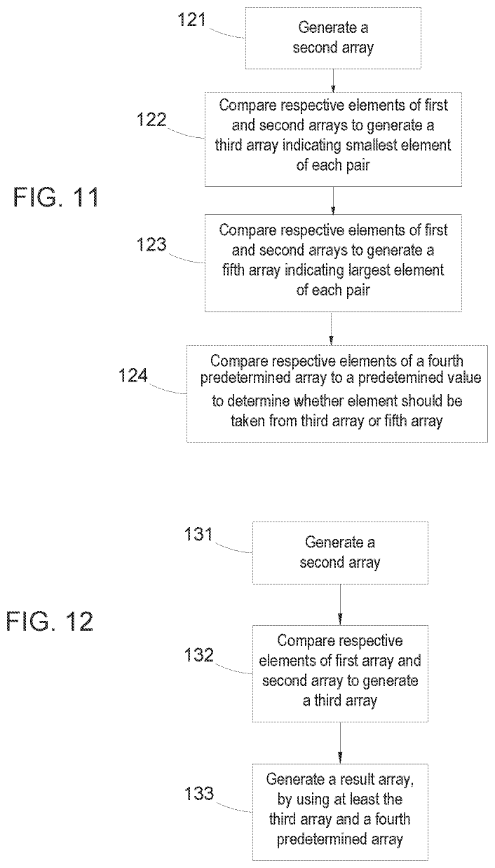

The second method is depicted in FIG. 11. For each phase a second array in which elements of the first array to be compared are swapped in step 121. In the next step 122 respective elements of the first and second arrays are compared to generate a third array comprising the smallest element of each pair. A fifth array, comprising the largest elements of each pair of element, is then generated 123 by comparing the first and second arrays. The second and third steps could be performed in either order. Lastly 124, the fourth predetermined array (which indicates the destination of the smaller element of each pair) is compared to a predetermined value to determine whether an element should be taken from the third array (comprising the smaller elements of each pair) or the fifth array (comprising the larger elements of each pair).

The method of the invention is depicted in FIG. 12, which is a summary of the methods depicted in FIGS. 7 and 11. In a first step 131 a second array in which the pairs of elements to be compared swapped is generated. In a second step 132 elements of the first array and second array are compared to generate a third array. The third array may indicate which of the first and second element has the smaller respective element (as in the first method) or it may comprise the smaller elements. A fourth array indicates the destination of the larger and smaller elements of each pair. In a final step 133 a result array is generated by using a fourth predetermined array to indicate the destination of the larger and smaller of each pair. This may be achieved by using the fourth array to select an element from either the third array or a fifth array (comprising the larger of each pair of elements), as in the second method. Alternatively (as in the first described method) it may be achieved by processing the fourth predetermined array with the third array to generate a fifth array indicating whether the elements should be taken from the first array or the second array.

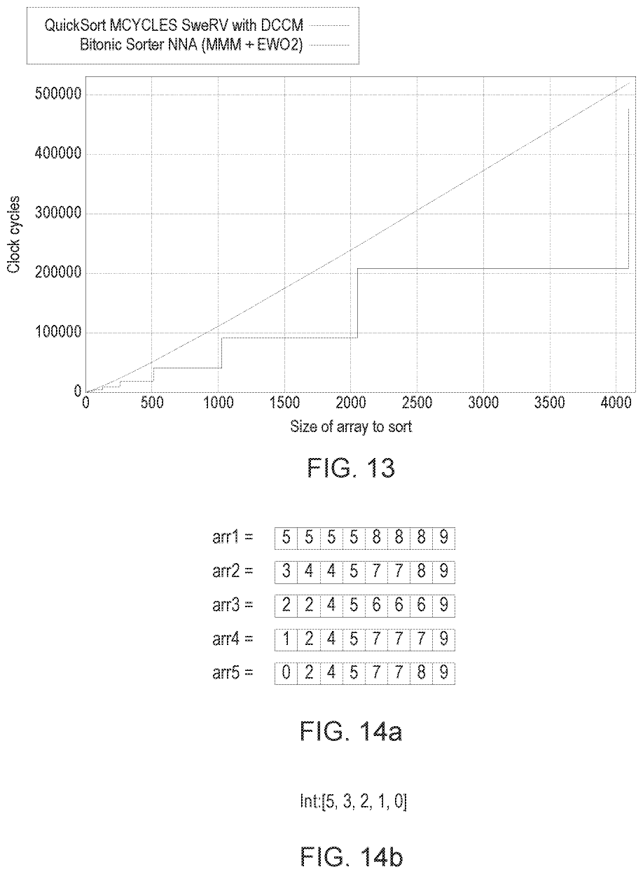

The present invention therefore provides a method of sorting an array within a predetermined number of steps and therefore within a deterministic time. FIG. 13 depicts the number of clock cycles to sort a random array of specific sizes. The dashed line indicates the time taken to sort the random array using a quicksort algorithm. Depending on how well sorted the array is to start with the quicksort algorithm may take longer or shorter than indicated in FIG. 13. The second line depicts the time taken using the present invention. In contrast to the time taken for the quicksort algorithm the time taken for the present invention is deterministic i.e. it does not vary depending on the original order of the array. As can be seen the time taken for the present invention is less than using a quicksort algorithm.

The example above sorts an array of size 4. Additional stages could be used to sort arrays of size 8, 16, 32, etc. If an array is not of a size 2ⁿ then additional elements can be added to make the array of a size 2ⁿ. The additional elements could be either the maximum value for the number of bits or the minimum value. For example, an array of size 5, with four bits per element (each element being an unsigned number) could have an additional three elements of 15. So an array [6, 3, 11, 7, 4] would become [6, 3, 11, 7, 4, 15, 15, 15]. The array now has eight elements and can now be sorted using a bitonic sorting algorithm of three stages and six phases. The additional elements could be added at the beginning of the input, or at the end (or anywhere, although it may be simpler for the system to add the elements at the beginning or the end, depending on the circumstances, rather than in the middle), but due to the deterministic nature of the bitonic sort algorithm the positions at which the additional elements are added does not affect the overall sort time.

The description above describes how data elements within an algorithm are sorted. The data elements often have an identification or location. For example, the elements may represent a variable of a data block (with an identification or location) and the elements must be linked back to the data block. This can be achieved using compound numbers such that the identification is appended onto the end of the number. As the element forms the more significant bits, the compound number will be sorted according to the element (rather than the identification). The identification and the element are therefore linked and, once the bitonic sorting algorithm is complete, the identification can be extracted from the compound number to identify, for example, the data block. An example is given:

| Number | | Identification | | Compound Number | |
|---|---|---|---|---|---|
| Decimal | Binary | Decimal | Binary | Binary | Decimal |
| 10 | 1010 | 0 | 0000 | 10100000 | 160 |
| 5 | 0101 | 1 | 0001 | 01010001 | 81 |
| 6 | 0110 | 2 | 0010 | 01100010 | 98 |
| 1 | 0001 | 3 | 0011 | 00010011 | 19 |

The present invention can be used on the compound numbers and an identical order of numbers will result.

An alternative to using compound numbers is to use a similar method to the sorting algorithm on the identification data, but use T5 (which indicates whether original pairs of elements or swapped pairs of elements should be used) generated from the original data elements. Thus, T1, would be the original identification elements, and T2 would have the elements of T1 swapped according to the corresponding phase of the bitonic sorting algorithm. Then, using T5 generated from the corresponding phase of the bitonic sorting algorithm a Toutput=LessThan (T5, 1, T1, T2). Thus, for each phase the identification elements would be sorted in the same way as the data elements.

This process can be repeated for each phase of the bitonic sorting algorithm until the identification elements of the identification array are sorted in exactly the same way as the data array. The identification elements would be sorted according to the size of their corresponding data element not based on the magnitude of the identification element itself.

NNAs sometimes need to order elements but they do not have a specific operation to achieve this. However, the present method provides a method of sorting elements of an array in parallel withing the NNA. Advantageously, the time taken is deterministic so only a specific amount of time, or clock cycles, need to be allocated to it in an algorithm.

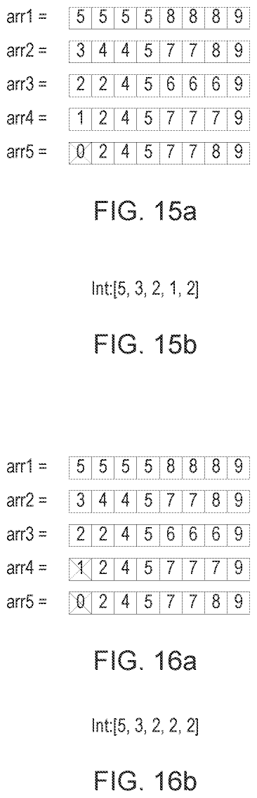

An alternative method of sorting an array which is not of a size 2ⁿ is to divide it into smaller sub-arrays of size 2ⁿ. For example an array of size 468 could be divided into an sub-arrays of size 256, 128, 64, 16 and 4. Some of the smaller sub-arrays may not be of size 2ⁿ. For example, an array of size 467 may be divided into sub-arrays of size 256, 128, 64, 16 and 3. An additional element may be added to the final sub-array (of either the maximum or minimum, depending on the sorting order) to make it an sub-array of size 4. The memory required by the merging algorithm increases by a factorial of the number of arrays to be merged so it may be advantageous to limit the number of sub-arrays into which the original array is divided. Once the array has been divided the elements of the sub-arrays can then be sorted according to size as described above. The sub-arrays must then be merged into a single, larger array ordered by size and the method for this is described below. FIGS. 14-18 depict a method of merging sub-arrays.

The method utilises different sets (or ‘blocks’) of program instructions for each different size order of elements in an incremental array, as described in more detail below. There is BLOCK(1, 2, 3, 4, 5), BLOCK(1, 2, 3, 5, 4), BLOCK(1, 2, 5, 3, 4) etc., where the numbers in brackets indicate the size order for the elements in the array. There are different blocks of code for all the different permutations of orders of the intermediate array. Depending on the size order of elements within the intermediate array different sets of program instructions are used, or accessed, as will now be explained with reference to the example depicted in FIGS. 14-18.

FIG. 14a depicts 5 sub-arrays of size 8, with the elements of each sorted by size. Additionally the sub-arrays have been sorted with the sub-array with the largest small value placed at the top and those with successively smaller smallest elements placed sequentially below.

An intermediate array is generated with the first element from each of the arrays (arr1[0], arr2[0], arr3[0], arr4[0], arr5[0]) and this is depicted in FIG. 14b. As the original sub-arrays were in order based on the order of their smallest value the intermediate array is also in incremental order and the order is order=(arr, 1, arr2, arr3, arr4, arr5). Thus, the set of program instructions, or block of code BLOCK (0, 1, 2, 3, 4), is accessed. BLOCK (0, 1, 2, 3, 4) comprises instructions to take the smallest element from intermediate array (i.e. arr5) and place it into an output array. In this example, the smallest element from the intermediate array is 0 (from array 5) and this is output as the first element in the output array. Then, the next value in the sub-array from which the element output to the output array originated is used to replace that output element in the intermediate array. So, in the present example, the next value in sub-array 5 (arr5[1]) replaces arr5[0] in the intermediate array and this is depicted in FIGS. 15a and 15b. The output array is therefore [0] at this stage.

As can be seen in FIG. 15b the individual elements of the intermediate array are not sorted. However, the size order of elements within the intermediate array is determined so, in this example, order=(arr1, arr2, arr3, arr5, arr4).

When the intermediate array is first generated the size order of the elements of the intermediate array are known because the sub-arrays are ordered according to the size of the first element. When a new element replaces an output element the new order can be replaced by comparing the new element to the next smallest element. If it is smaller, or the same size, then the order remains the same. If it is larger than the smallest element it can be compared to the second smallest. If it is smaller than the second smallest then the new order is determined. If it is larger than the second smallest it is then compared to the third smallest. This continues until the new size order of the intermediate array is determined.

As the order is order=(arr1, arr2, arr3, arr5, arr4) the block of code BLOCK(1, 2, 3, 5, 4) is therefore used. So, although the elements within the intermediate array themselves are not sorted the code used identifies which is the smallest element in the intermediate array at that point in time. As depicted in FIG. 16 BLOCK (1, 2, 3, 5, 4) takes the smallest element (arr4) and outputs to the output array, which at this point is [0, 1]. The next element in arr4 (arr4[1]) is placed as the fourth element in the intermediate array which is now [5, 3, 2, 2, 2]. The size order of elements within the intermediate array is determined and remains order=(arr1, arr2, arr3, arr5, arr4) so set of program instructions BLOCK(1, 2, 3, 5, 4) are again used.

Set of program instructions BLOCK (1, 2, 3, 5, 4) takes arr4 and outputs it to the output array, which is now [0, 1, 2]. As depicted in FIG. 17 arr4[2] replaces arr4[1] in the intermediate array and the order is determined to be order order=(arr1, arr4, arr2, arr3, arr5) so BLOCK (1, 4, 2, 3, 5) would be used next.

This process is repeated until all the elements of all the arrays have been output into the output array. Thus, for the present example, the output array would be [0, 1, 2, 2, 2, 2, 3, 4, 4, 4, 4, 4, 5, 5, 5, 5, 5, 5, 5, 5, 6, 6, 6, 7, 7, 7, 7, 7, 7, 7, 8, 8, 8, 8, 8, 9, 9, 9, 9, 9] in which all the elements from all the sorted arrays have been sorted incrementally.

As will be appreciated, the method of merging different sorted arrays can be used to combined arrays of different sizes.

An array of indices may be used to identify which element from the original arrays should be placed in the intermediate array. For example, when replacing arr4[0] with arr4[1] the “1” comes from an array of indices which gets incremented. The next time that the fourth element is the smallest arr4[2] will replace arr4[1].

Different blocks of code may be used according the order of all the elements of the intermediate array. Thus BLOCK(0, 1, 2, 3, 4) refers to the block of code used when the largest element being at position 0 in the intermediate array, the next largest being at position 1 in the intermediate array. BLOCK (0, 4, 1, 2, 3) refers to the block of code for the intermediate array [5, 3, 2, 2, 4] when the largest element is at position 0, the next largest element is at position, 4, the next largest is at position 1, the next largest at position 2 and the smallest element is at position 3. There are different blocks of code for all the different permutations of orders of the intermediate array. Thus, when a new element replaces an existing element (in each step of the process) the new element needs to be compared to the next smallest element. If it is not smaller than that element it needs to be compared to the second smallest element etc. This continues until the order within the intermediate array has been identified so the next BLOCK of code can be identified and used.

Although the method of combining arrays described above is described in conjunction with arrays in ascending order, it can equally be applied to arrays in descending order.

Prior to merging, the maximum (or minimum if the order is reversed) value can be placed at the end of each sorted array as a supplementary element. This has the advantage that it is not necessary to know the length of each array and therefore reduces steps and improves performance. Thus, the intermediate array will eventually be filled with the supplementary elements. As these are the maximum value and other elements are smaller they will not be output into the output array.

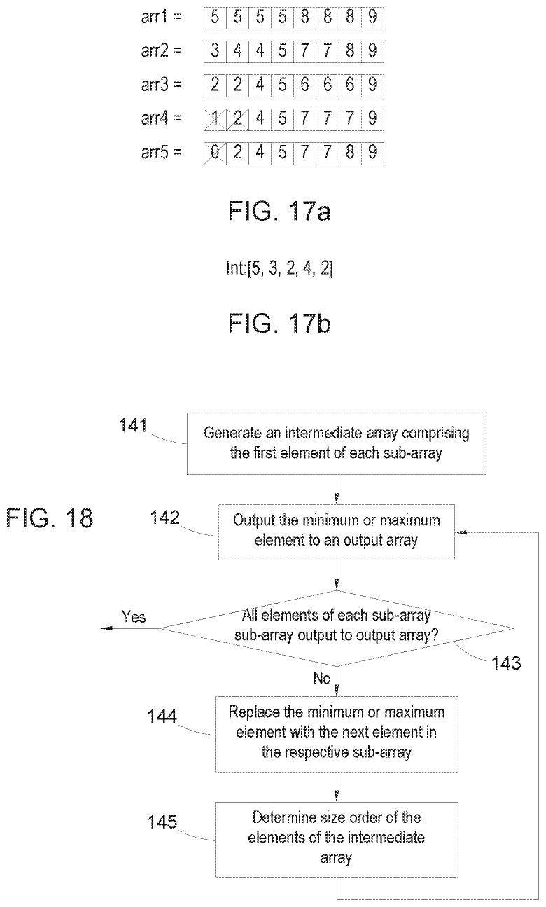

FIG. 18 depicts a method of merging sub-arrays according to the invention. In a first step 141 an intermediate array comprising the first element from each sub-array is generated. As discussed above, the size order of the elements within the initially generated intermediate array is known as the sub-arrays were already ordered. In a second step 142 either the maximum or minimum element from the intermediate array is output (based on the known size order of elements within the intermediate array).

Whether all elements of each sub-array have been output to the output array is assessed in step 143. Assessing whether all elements of each sub-array have been output to the output array may be achieved by the use of a counter counting the number of elements output to the output array. This value may be compared to the total elements in all the sub-arrays (excluding supplementary elements). If these values are equal all the elements have been output. If all elements of each sub-array have not been output to the output array the output element (the maximum or minimum element) is replaced with the next element in the respective sub-array. The size order of elements of the intermediate array is then determined in step 145. As described above, this allows the appropriate set of program instructions to be accessed or used. The process then returns to step 142. In this way a plurality of sub-arrays can be merged.

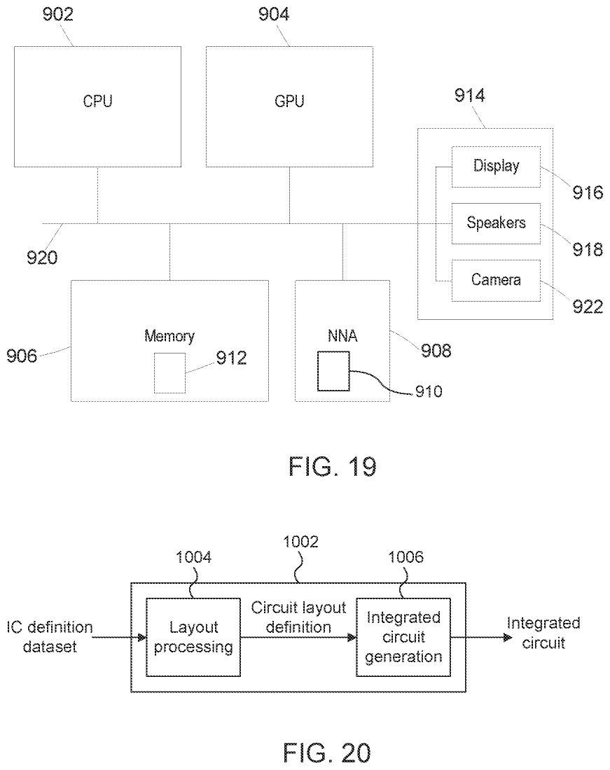

FIG. 19 shows a computer system in which processing systems described herein may be implemented. The computer system comprises a CPU 902, a GPU 904, a memory 906, a neural network accelerator (NNA) 908 and other devices 914, such as a display 916, speakers 918 and a camera 922. A processing block 910 (carrying out the method described above) is implemented on the NNA 908. In other examples, one or more of the depicted components may be omitted from the system, and/or the processing block 910 may be implemented on the GPU 904 or within the CPU 902. The components of the computer system can communicate with each other via a communications bus 920. A store 912 is implemented as part of the memory 906.

The hardware units described herein may be embodied in hardware on an integrated circuit. The hardware units described herein may be configured to perform any of the methods described herein. Generally, any of the functions, methods, techniques or components described above can be implemented in software, firmware, hardware (e.g., fixed logic circuitry), or any combination thereof. The terms “module,” “functionality,” “component”, “element”, “unit”, “block” and “logic” may be used herein to generally represent software, firmware, hardware, or any combination thereof. In the case of a software implementation, the module, functionality, component, element, unit, block or logic represents program code that performs the specified tasks when executed on a processor. The algorithms and methods described herein could be performed by one or more processors executing code that causes the processor(s) to perform the algorithms/methods. Examples of a computer-readable storage medium include a random-access memory (RAM), read-only memory (ROM), an optical disc, flash memory, hard disk memory, and other memory devices that may use magnetic, optical, and other techniques to store instructions or other data and that can be accessed by a machine.

The terms computer program code and computer readable instructions as used herein refer to any kind of executable code for processors, including code expressed in a machine language, an interpreted language or a scripting language. Executable code includes binary code, machine code, bytecode, code defining an integrated circuit (such as a hardware description language or netlist), and code expressed in a programming language code such as C, Java or OpenCL. Executable code may be, for example, any kind of software, firmware, script, module or library which, when suitably executed, processed, interpreted, compiled, executed at a virtual machine or other software environment, cause a processor of the computer system at which the executable code is supported to perform the tasks specified by the code.

A processor, computer, or computer system may be any kind of device, machine or dedicated circuit, or collection or portion thereof, with processing capability such that it can execute instructions. A processor may be or comprise any kind of general purpose or dedicated processor, such as a CPU, GPU, NNA, System-on-chip, state machine, media processor, an application-specific integrated circuit (ASIC), a programmable logic array, a field-programmable gate array (FPGA), or the like. A computer or computer system may comprise one or more processors.

It is also intended to encompass software which defines a configuration of hardware as described herein, such as HDL (hardware description language) software, as is used for designing integrated circuits, or for configuring programmable chips, to carry out desired functions. That is, there may be provided a computer readable storage medium having encoded thereon computer readable program code in the form of an integrated circuit definition dataset that when processed (i.e. run) in an integrated circuit manufacturing system configures the system to manufacture a hardware unit configured to perform any of the methods described herein, or to manufacture a hardware unit comprising any apparatus described herein. An integrated circuit definition dataset may be, for example, an integrated circuit description.

Therefore, there may be provided a method of manufacturing, at an integrated circuit manufacturing system, a hardware unit as described herein. Furthermore, there may be provided an integrated circuit definition dataset that, when processed in an integrated circuit manufacturing system, causes the method of manufacturing a hardware unit to be performed.

An integrated circuit definition dataset may be in the form of computer code, for example as a netlist, code for configuring a programmable chip, as a hardware description language defining hardware suitable for manufacture in an integrated circuit at any level, including as register transfer level (RTL) code, as high-level circuit representations such as Verilog or VHDL, and as low-level circuit representations such as OASIS (RTM) and GDSII. Higher level representations which logically define hardware suitable for manufacture in an integrated circuit (such as RTL) may be processed at a computer system configured for generating a manufacturing definition of an integrated circuit in the context of a software environment comprising definitions of circuit elements and rules for combining those elements in order to generate the manufacturing definition of an integrated circuit so defined by the representation. As is typically the case with software executing at a computer system so as to define a machine, one or more intermediate user steps (e.g. providing commands, variables etc.) may be required in order for a computer system configured for generating a manufacturing definition of an integrated circuit to execute code defining an integrated circuit so as to generate the manufacturing definition of that integrated circuit.

An example of processing an integrated circuit definition dataset at an integrated circuit manufacturing system so as to configure the system to manufacture a hardware unit will now be described with respect to FIG. 20.

FIG. 20 shows an example of an integrated circuit (IC) manufacturing system 1002 which is configured to manufacture a hardware unit as described in any of the examples herein. In particular, the IC manufacturing system 1002 comprises a layout processing system 1004 and an integrated circuit generation system 1006. The IC manufacturing system 1002 is configured to receive an IC definition dataset (e.g. defining a hardware unit as described in any of the examples herein), process the IC definition dataset, and generate an IC according to the IC definition dataset (e.g. which embodies a hardware unit as described in any of the examples herein). The processing of the IC definition dataset configures the IC manufacturing system 1002 to manufacture an integrated circuit embodying a hardware unit as described in any of the examples herein.

The layout processing system 1004 is configured to receive and process the IC definition dataset to determine a circuit layout. Methods of determining a circuit layout from an IC definition dataset are known in the art, and for example may involve synthesising RTL code to determine a gate level representation of a circuit to be generated, e.g. in terms of logical components (e.g. NAND, NOR, AND, OR, MUX and FLIP-FLOP components). A circuit layout can be determined from the gate level representation of the circuit by determining positional information for the logical components. This may be done automatically or with user involvement in order to optimise the circuit layout. When the layout processing system 1004 has determined the circuit layout it may output a circuit layout definition to the IC generation system 1006. A circuit layout definition may be, for example, a circuit layout description.

The IC generation system 1006 generates an IC according to the circuit layout definition, as is known in the art. For example, the IC generation system 1006 may implement a semiconductor device fabrication process to generate the IC, which may involve a multiple-step sequence of photo lithographic and chemical processing steps during which electronic circuits are gradually created on a wafer made of semiconducting material. The circuit layout definition may be in the form of a mask which can be used in a lithographic process for generating an IC according to the circuit definition. Alternatively, the circuit layout definition provided to the IC generation system 1006 may be in the form of computer-readable code which the IC generation system 1006 can use to form a suitable mask for use in generating an IC.

The different processes performed by the IC manufacturing system 1002 may be implemented all in one location, e.g. by one party. Alternatively, the IC manufacturing system 1002 may be a distributed system such that some of the processes may be performed at different locations, and may be performed by different parties. For example, some of the stages of: (i) synthesising RTL code representing the IC definition dataset to form a gate level representation of a circuit to be generated, (ii) generating a circuit layout based on the gate level representation, (iii) forming a mask in accordance with the circuit layout, and (iv) fabricating an integrated circuit using the mask, may be performed in different locations and/or by different parties.

In other examples, processing of the integrated circuit definition dataset at an integrated circuit manufacturing system may configure the system to manufacture a hardware unit without the IC definition dataset being processed so as to determine a circuit layout. For instance, an integrated circuit definition dataset may define the configuration of a reconfigurable processor, such as an FPGA, and the processing of that dataset may configure an IC manufacturing system to generate a reconfigurable processor having that defined configuration (e.g. by loading configuration data to the FPGA).

In some embodiments, an integrated circuit manufacturing definition dataset, when processed in an integrated circuit manufacturing system, may cause an integrated circuit manufacturing system to generate a device as described herein. For example, the configuration of an integrated circuit manufacturing system in the manner described above with respect to FIG. 20 by an integrated circuit manufacturing definition dataset may cause a device as described herein to be manufactured.

In some examples, an integrated circuit definition dataset could include software which runs on hardware defined at the dataset or in combination with hardware defined at the dataset. In the example shown in FIG. 20, the IC generation system may further be configured by an integrated circuit definition dataset to, on manufacturing an integrated circuit, load firmware onto that integrated circuit in accordance with program code defined at the integrated circuit definition dataset or otherwise provide program code with the integrated circuit for use with the integrated circuit.

The implementation of concepts set forth in this application in devices, apparatus, modules, and/or systems (as well as in methods implemented herein) may give rise to performance improvements when compared with known implementations. The performance improvements may include one or more of increased computational performance, reduced latency, increased throughput, and/or reduced power consumption. During manufacture of such devices, apparatus, modules, and systems (e.g. in integrated circuits) performance improvements can be traded-off against the physical implementation, thereby improving the method of manufacture. For example, a performance improvement may be traded against layout area, thereby matching the performance of a known implementation but using less silicon. This may be done, for example, by reusing functional blocks in a serialised fashion or sharing functional blocks between elements of the devices, apparatus, modules and/or systems. Conversely, concepts set forth in this application that give rise to improvements in the physical implementation of the devices, apparatus, modules, and systems (such as reduced silicon area) may be traded for improved performance. This may be done, for example, by manufacturing multiple instances of a module within a predefined area budget.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein. In view of the foregoing description it will be evident to a person skilled in the art that various modifications may be made within the scope of the invention.

What is claimed is:

1. A method of comparing a plurality of elements in a first array using a neural network accelerator comprising fixed-function hardware, the method comprising:
generating a second array, the second array having the position of each pair of elements to be compared swapped;
comparing respective elements of the first array and the second array to generate a third array to identify which of the respective elements of the first and second array is larger or smaller; and
generating a result array, using at least the third array, by using a fourth predetermined array, the fourth predetermined array indicating the position in the result array of the larger and the smaller of each element of each pair of elements.

2. The method according to claim 1, wherein generating a result array comprises:
processing, using a XOR function, the third array with the fourth predetermined array to output a fifth array which indicates whether each pair of elements should be taken from the first array in which the pair of elements are in the original position or the second array in which the pair of elements are in the swapped position;
generating a result array, based on the information in the fifth array, using elements from at least one of the first array and the second array.

3. The method according to claim 1, wherein generating a result array comprises comparing the fifth array with a predetermined value.

4. The method according to claim 3, wherein comparing the fifth array with a predetermined value comprises one or more of the following functions: more than, less than, more than or equal to, less than or equal to.

5. The method according to claim 1, wherein the third array comprises the smaller of each pair of elements and generating a result array comprises:
comparing respective elements of the first array and the second array to generate a fifth array comprising the larger of each pair; and
comparing elements of a fourth predetermined array to a predetermined value to determine whether an element should be taken from the third array or the fifth array.

6. The method according to claim 5, wherein comparing elements of a fourth predetermined array to a predetermined value comprises one or more of the following functions: more than, less than, more than or equal to, less than or equal to.

7. The method according to claim 1, wherein the method is repeated a plurality of times, each time forming a comparison step in a bitonic sorting algorithm, the method being repeated until the bitonic sorting algorithm is complete.

8. The method according to claim 7 wherein, for each repetition, the pairs of elements to be compared are independent and selected according to the comparison step in the bitonic sorting algorithm.

9. The method according to claim 7, wherein the fourth predetermined array is independent for each repetition of the method and is predetermined according to the comparison step in the bitonic sorting algorithm.

10. The method according to claim 1, wherein the elements in the array are sorted into an incremental order.

11. The method according to claim 1 wherein, if the number of elements in the first array is not a power of 2, elements are added to the first array until the number of elements is a power of 2, each element added being the same of either a maximum value or a minimum value.

12. The method according to claim 1, wherein the method is carried out using elementwise operations.

13. The method according to claim 1, wherein the neural network accelerator does not comprise dedicated sorting hardware.

14. The method according to claim 1, wherein the elements to be sorted are object predictions in a non-maximum suppression layer in an object detection network.

15. A method of dividing an array into a plurality of sub-arrays, comprising:
performing the method as set forth in claim 1 on each of the sub-arrays; and
merging the sub-arrays to an output array having a plurality of elements, the merging comprising:
generating an intermediate array comprising the first element from each sub-array,
outputting the maximum or minimum element as the next element in an output array,
replacing the maximum or minimum element in the intermediate array with a new element, wherein the new element is the next element in the respective sub-array, and
determining a size order of the elements of the intermediate array;
wherein the steps of outputting the maximum or minimum element, replacing the maximum or minimum element and determining the size order of the elements of the intermediate array are repeated until all the elements from the plurality of sub-arrays have been output to the output array.

16. The method according to claim 15, wherein outputting the maximum or minimum element as the next element in an output array and replacing the maximum or minimum element in the respective sub-array comprises accessing a different set of program instructions based on the determined size order of the elements in the intermediate array.

17. The method according to claim 15, further comprising, before generating the intermediate array, ordering the sub-arrays based on the first element of each of the plurality of sub-arrays.

18. A graphics processing system configured to perform the method as set forth in claim 1.

19. A non-transitory computer readable storage medium having stored thereon computer readable code configured to cause the method as set forth in claim 1 to be performed when the code is run.

20. A non-transitory computer readable storage medium having stored thereon a computer readable dataset description of a graphics processing system as set forth in claim 18 that, when processed in an integrated circuit manufacturing system, causes the integrated circuit manufacturing system to manufacture an integrated circuit embodying the graphics processing system.
